(19) United States
(12) Patent Application Publication
(10) Pub. No.: US 2025/0194220 A1
(43) Pub. Date: Jun. 12, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Yuki TSUTSUURA, Tokyo (JP)

(73) Assignee: Mitsubishi Electric Corporation, Tokyo (JP)

(21) Appl. No.: 18/896,803

(22) Filed: Sep. 25, 2024

(30) Foreign Application Priority Data
Dec. 7, 2023 (JP) 2023-206637

(51) Int. Cl. H01L 29/49; H01L 29/40; H01L 29/423; H01L 29/51

(52) U.S. Cl. CPC H10D 64/671; H10D 64/01; H10D 64/514; H10D 64/68

(57) ABSTRACT

The object is to provide a technology capable of enhancing the reliability of a semiconductor device. A semiconductor device includes: an insulating film along an upper surface of a semiconductor substrate; a first surface electrode selectively provided on the insulating film; and a passivation film covering the insulating film and the first surface electrode. The passivation film includes a cover portion covering the first surface electrode, the cover portion having a tapered shape with at least one of a first structure or a second structure such that the cover portion becomes wider as the cover portion is closer to the semiconductor substrate in a cross-sectional view.

### BACKGROUND OF THE INVENTION

### Field of the Invention

The present disclosure relates to a semiconductor device and a method of manufacturing the semiconductor device.

### Description of the Background Art

Various techniques on semiconductor devices have been proposed. For example, Japanese Patent Application Laid-Open No. 2010-062421 proposes a technology for covering a surface electrode connected to a guard ring, with a passivation film such as an interlayer film.

In a known art, however, a side surface of the surface electrode rises vertically with respect to an upper surface of a semiconductor substrate. Accordingly, a side surface of a portion of the passivation film which covers the surface electrode also rises vertically with respect to the upper surface of the semiconductor substrate. In such a structure, the vertically rising portion of the passivation film is prone to have cracks due to concentration of stresses such as a thermal stress. Thus, the surface electrode is sometimes subject to corrosion due to moisture ingress from a crack to an end of a chip during a temperature humidity bias (THB) reliability test. This consequently causes a problem of decrease in the reliability of the semiconductor device.

### SUMMARY

The present disclosure has been conceived in view of the problem, and the object is to provide a technology capable of enhancing the reliability of a semiconductor device.

A semiconductor device according to the present disclosure includes: a semiconductor substrate having an end; an insulating film along an upper surface of the semiconductor substrate; a first surface electrode selectively provided on the insulating film; and a passivation film covering the insulating film and the first surface electrode, wherein the passivation film includes a cover portion covering the first surface electrode, the cover portion having a tapered shape with at least one of a first structure or a second structure such that the cover portion becomes wider as the cover portion is closer to the semiconductor substrate in a cross-sectional view, in the first structure, the first surface electrode includes a first metal portion, and a second metal portion made of a metal with corrosion resistance higher than corrosion resistance of the first metal portion, the second metal portion being in contact with a side surface of the first metal portion on a same side as the end of the semiconductor substrate in a plan view, and having a tapered shape such that the second metal portion becomes wider as the second metal portion is closer to the semiconductor substrate in the cross-sectional view, and in the second structure, a first angle between a side surface of the cover portion and the upper surface of the semiconductor substrate on the cover portion side is smaller in the cross-sectional view than a second angle between a side surface of the first surface electrode and the upper surface of the semiconductor substrate on the first surface electrode side.

This can enhance the reliability of the semiconductor device.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view illustrating a structure of a semiconductor device according to Embodiment 1;

FIG. 2 is a cross-sectional view illustrating a structure of a termination region of the semiconductor device according to Embodiment 1;

FIG. 3 is a cross-sectional view illustrating a process of manufacturing the semiconductor device according to Embodiment 1;

FIG. 4 is a cross-sectional view illustrating a process of manufacturing the semiconductor device according to Embodiment 1;

FIG. 5 is a cross-sectional view illustrating a structure of a termination region of a semiconductor device according to Embodiment 2;

FIG. 6 is a cross-sectional view illustrating a process of manufacturing the semiconductor device according to Embodiment 2;

FIG. 7 is a cross-sectional view illustrating a process of manufacturing the semiconductor device according to Embodiment 2;

FIG. 8 is a cross-sectional view illustrating a structure of a termination region of a semiconductor device according to Embodiment 3;

FIG. 9 is a cross-sectional view illustrating a process of manufacturing the semiconductor device according to Embodiment 3;

FIG. 10 is a cross-sectional view illustrating a process of manufacturing the semiconductor device according to Embodiment 3;

FIG. 11 is a cross-sectional view illustrating a process of manufacturing a semiconductor device according to Embodiment 4;

FIG. 12 is a cross-sectional view illustrating a process of manufacturing the semiconductor device according to Embodiment 4;

FIG. 13 is a cross-sectional view illustrating a process of manufacturing the semiconductor device according to Embodiment 4;

FIG. 14 is a cross-sectional view illustrating a process of manufacturing the semiconductor device according to Embodiment 4;

FIG. 15 is a cross-sectional view illustrating a process of manufacturing a semiconductor device according to Embodiment 5;

FIG. 16 is a cross-sectional view illustrating a structure of a termination region of a semiconductor device according to Embodiment 6;

FIG. 17 is a cross-sectional view illustrating a structure of a termination region of a semiconductor device according to Embodiment 7;

FIG. 18 is a cross-sectional view illustrating a process of manufacturing the semiconductor device according to Embodiment 7;

FIG. 19 is a cross-sectional view illustrating a process of manufacturing the semiconductor device according to Embodiment 7; and

FIG. 20 is a cross-sectional view illustrating a process of manufacturing the semiconductor device according to Embodiment 7.

### DESCRIPTION OF THE PREFERRED EMBODIMENTS

Hereinafter, Embodiments will be described with reference to the accompanying drawings. The features to be described in Embodiments below are mere exemplification, and all of the features are not necessarily essential. In the description below, identical constituent elements in a plurality of Embodiments will be denoted by the same or similar reference numerals, and the different constituent elements will be mainly described. In the following description, a particular position and a particular direction such as “up”, “down”, “left”, “right”, “front”, or “back” need not always coincide with an actual position and an actual direction. Furthermore, n-type and p-type may be replaced with p-type and n-type, respectively, in the following description.

### Embodiment 1

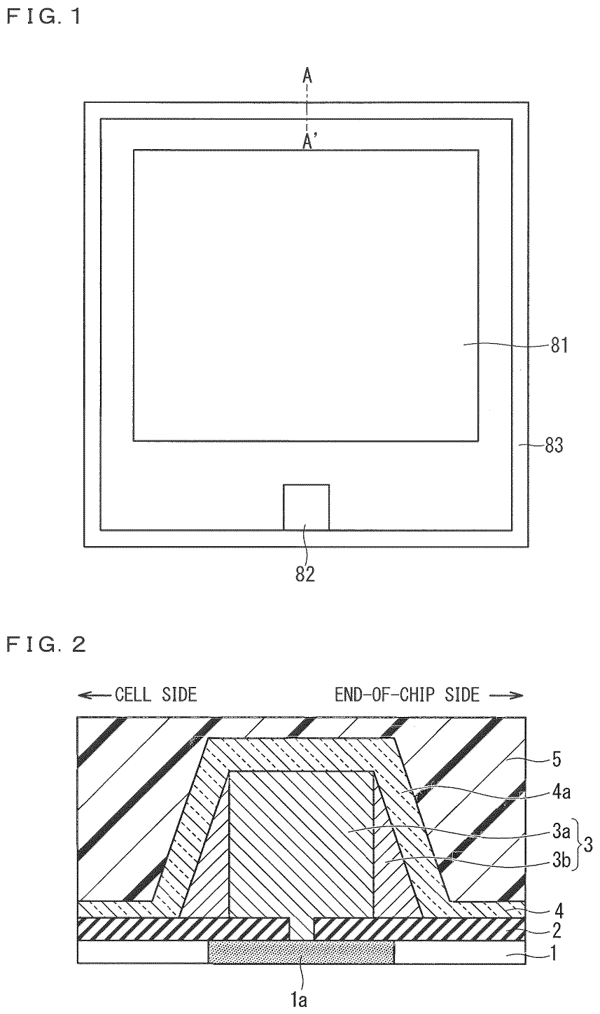

FIG. 1 is a plan view illustrating a structure of a semiconductor device according to Embodiment 1. As illustrated in FIG. 1, a cell region 81, a pad region 82, and a termination region 83 are defined in the semiconductor device according to Embodiment 1.

The cell region 81 is a region including a plurality of semiconductor elements. The semiconductor elements include, for example, at least one of a metal oxide semiconductor field-effect transistor (MOSFET), an insulated-gate bipolar transistor 10 (IGBT), a reverse-conducting IGBT (RC-IGBT), a Schottky barrier diode (SBD), or a PN junction diode (PND). In this SPECIFICATION, for example, at least one of A, B, C, . . . , or Z means any one of all combinations obtained by combining one type or more extracted from each of groups of A, B, C, . . . , and Z.

The pad region 82 is a region including a control pad for controlling the semiconductor elements in the cell region 81. The control pad may include, for example, a current sense pad, a Kelvin emitter pad, a gate pad, and a temperature sensing diode pad.

The current sense pad is a control pad for detecting a current flowing through the cell region 81 of the semiconductor device. This current sense pad is a control pad electrically connected to a part of the cell region 81 so that a fraction to one several ten-thousandth of the current flowing through the entirety of the cell region 81 flows through the current sense pad when the current flows through the cell region 81. The Kelvin emitter pad and the gate pad are control pads to which a gate drive voltage for controlling on/off of the semiconductor device is applied. The Kelvin emitter pad is electrically connected to a p-type base layer of the cell region 81. The gate pad is electrically connected to gate electrodes of the cell region 81. The temperature sensing diode pad is a control pad electrically connected to an anode and a cathode of a temperature sensing diode of the semiconductor device. A voltage between the anode and the cathode of the temperature sensing diode is measured. The temperature sensing diode, which is not illustrated, is disposed in the cell region 81. Then, the temperature of the semiconductor device is measured based on the voltage.

The termination region 83 for maintaining the breakdown voltage of the semiconductor device is disposed around a region obtained by combining the cell region 81 and the pad region 82. The termination region 83 appropriately has a breakdown voltage maintaining structure. The breakdown voltage maintaining structure may be established by, for example, a field limiting ring (FLR) surrounding the cell region 81 with p-type termination well layers of a p-type semiconductor or variation of lateral doping (VLD) surrounding the cell region 81 with p-type termination well layers having a concentration slope, on a first main surface that is a front side of the semiconductor device. The number of the ring-shaped p-type termination well layers to be used for the FLR and the concentration distribution of the VLD should be appropriately selected according to the design of the breakdown voltage of the semiconductor device. The p-type termination well layers may be formed on almost the whole pad region 82. Alternatively, a part of the cell region 81 may be formed in the pad region 82.

FIG. 2 is a cross-sectional view illustrating a structure of the termination region 83 of the semiconductor device according to Embodiment 1, specifically, a cross-sectional view taken along the line A-A′ of FIG. 1. As illustrated in FIG. 2, the semiconductor device according to Embodiment 1 includes a semiconductor substrate 1, an insulating film 2, a first surface electrode 3, a glass coat 4 that is a passivation film, and a polyimide film 5.

The end of the semiconductor substrate 1 corresponds to a perimeter of the termination region 83 in FIG. 1. In cross-sectional views of FIG. 2 and the subsequent drawings, the right side of the view corresponds to the end side of the semiconductor substrate 1, and the left side of the view corresponds to the cell region 81 side in the semiconductor substrate 1. The illustration of, for example, a lower portion of the semiconductor substrate 1 is omitted in the cross-sectional views of FIG. 2 and the subsequent drawings for convenience.

The semiconductor substrate 1 may be made of silicon (Si) or a wide bandgap semiconductor. The wide bandgap semiconductor includes, for example, at least one of silicon carbide (SiC), silicon nitride (SiN), gallium oxide (Ga₂O₃), gallium nitride (GaN), or diamond. Particularly, a higher electric field can be applied to the termination region 83 in the semiconductor substrate 1 made of SiC than that in a semiconductor substrate made of Si. Furthermore, the semiconductor substrate 1 may be obtained from a normal semiconductor wafer or an epitaxial growth layer.

The semiconductor substrate 1 includes a guard ring region 1a that is a p-type termination well layer. The guard ring region 1a is ring-shaped similarly to the termination region 83 in a plan view. Although the number of the guard ring regions 1a in FIG. 2 is one, the number may be multiple. A region in contact with the guard ring region 1a in the semiconductor substrate 1 is, for example, of n-type.

The insulating film 2 is, for example, an oxide film, and is formed along the upper surface of the semiconductor substrate 1. Although the insulating film 2 is formed directly on the semiconductor substrate 1 in FIG. 2, the insulating film 2 may be formed indirectly on the semiconductor substrate 1.

The first surface electrode 3 is selectively provided on the insulating film 2. The first surface electrode 3 in Embodiment 1 is electrically connected to the guard ring region 1a through a contact hole of the insulating film 2, and functions as a field plate for maintaining the breakdown voltage. Typically, an electric field in driving the semiconductor elements is prone to concentrate on an interface between the insulating film 2 and the guard ring region 1a directly below the contact hole of the insulating film 2. Since the first surface electrode 3 functioning as the field plate can reduce such electric field concentration, the first surface electrode 3 can increase the breakdown voltage. Although the first surface electrode 3 in Embodiment 1 functions as the field plate, the first surface electrode 3 need not function as the field plate.

The first surface electrode 3 in Embodiment 1 includes a first metal portion 3a and a second metal portion 3b. The first metal portion 3a is made of, for example, AlSi. The first metal portion 3a may have a laminated structure consisting of a plurality of layers.

The second metal portion 3b is made of a metal with corrosion resistance higher than that of the first metal portion 3a, for example, tungsten. The second metal portion 3b is formed in contact with a side surface of the first metal portion 3a on the same side as the end of the semiconductor substrate 1 in a plan view. In other words, the second metal portion 3b is formed in contact with the right side surface of the first metal portion 3a in FIG. 2. As illustrated in the example of FIG. 2, the second metal portion 3b may be formed in contact with not only the right side surface of the first metal portion 3a but also the left side surface of the first metal portion 3a. The second metal portion 3b has a tapered shape such that the second metal portion 3b becomes wider as the second metal portion 3b is closer to the semiconductor substrate 1 in a cross-sectional view, that is, toward a lower portion of the second metal portion 3b in FIG. 2.

The glass coat 4 continuously covers the insulating film 2 and the first surface electrode 3. With a first structure of the first surface electrode 3 including the first metal portion 3a and the second metal portion 3b as described above, a cover portion 4a of the glass coat 4 which covers the first surface electrode 3 has a tapered shape such that the cover portion 4a becomes wider as the cover portion 4a is closer to the semiconductor substrate 1 in a cross-sectional view. The glass coat 4 may have a laminated structure consisting of, for example, a SInSiN film and a SiN film. The SInSiN film can stabilize the termination breakdown voltage by correcting field nonuniformity caused by varying interface charges Qss and mobile ions from the outside (e.g., a mold resin). The SiN film can function as a protective film for preventing moisture ingress.

The polyimide film 5 covers the glass coat 4. The overcoating structure using the polyimide film 5 can reduce external influence. In the cross-sectional views subsequent to FIG. 2, the illustration of the polyimide film 5 may be omitted.

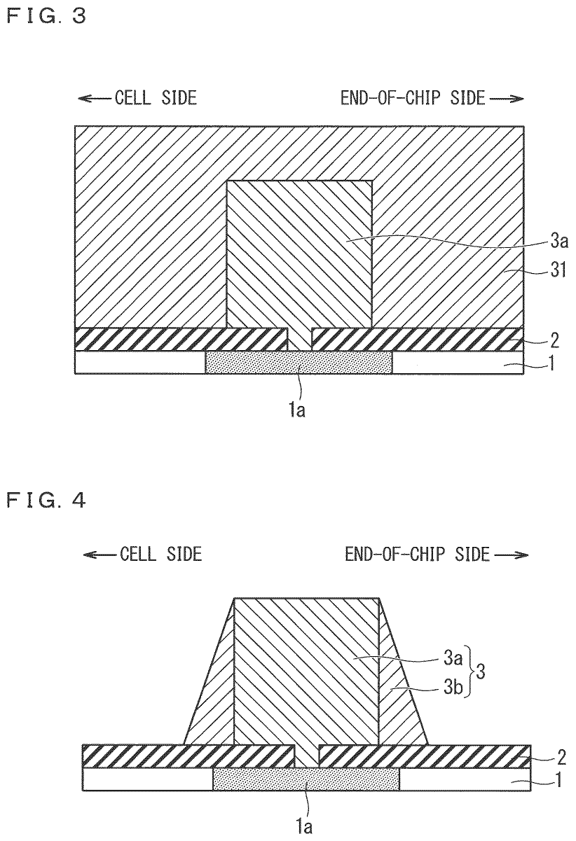

FIGS. 3 and 4 are cross-sectional views illustrating processes of manufacturing the semiconductor device according to Embodiment 1. First, the insulating film 2 is formed on the upper surface of the semiconductor substrate 1 including the guard ring region 1a, through a film formation process such as chemical vapor deposition (CVD), physical vapor deposition (PVD), or thermal oxidation as illustrated in FIG. 3. Then, patterning through an exposure process, a development process, and an etching process forms a contact hole in the insulating film 2.

Next, a conductive component made of, for example, AlSi is formed on the guard ring region 1a and the insulating film 2 through the film formation process. Then, patterning the conductive component forms the first metal portion 3a. Next, for example, a conductive component 31 made of, for example, tungsten is formed on the insulating film 2 and the first metal portion 3a through the film formation process.

Then, patterning the conductive component 31, such as etching back the conductive component 31 forms the second metal portion 3b having a tapered shape in a cross-sectional view as illustrated in FIG. 4. This consequently forms the first surface electrode 3 having a tapered shape in a cross-sectional view as a whole.

Then, the glass coat 4 continuously covering the insulating film 2 and the first surface electrode 3 is formed. The cover portion 4a of the glass coat 4 has a tapered shape in a cross-sectional view, with the first structure of the first surface electrode 3 having the tapered shape. Then, forming the polyimide film 5 covering the glass coat 4 completes the semiconductor device in FIG. 2.

### Summary of Embodiment 1

In the semiconductor device according to Embodiment 1, the glass coat 4 includes the cover portion 4a covering the first surface electrode 3, the cover portion 4a having a tapered shape such that the cover portion 4a becomes wider as the cover portion 4a is closer to the semiconductor substrate 1 in a cross-sectional view. Thus, a structure in which the side surface of the cover portion 4a obliquely rises with respect to the upper surface of the semiconductor substrate 1 can reduce cracks caused by concentration of stresses such as a thermal stress more than a structure in which the side surface vertically rises. This can prevent corrosion of the first surface electrode 3 due to moisture ingress from a crack to an end of a chip during a temperature humidity bias (THB) reliability test. Consequently, the reliability of the semiconductor device can be enhanced.

In Embodiment 1, the second metal portion 3b made of a metal with corrosion resistance higher than corrosion resistance of the first metal portion 3a is in contact with a side surface of the first metal portion 3a on the same side as the end of the semiconductor substrate 1 in a plan view. Even when a crack appears, such a structure can prevent corrosion of the first surface electrode 3 due to moisture ingress from the crack to an end of a chip.

### Embodiment 2

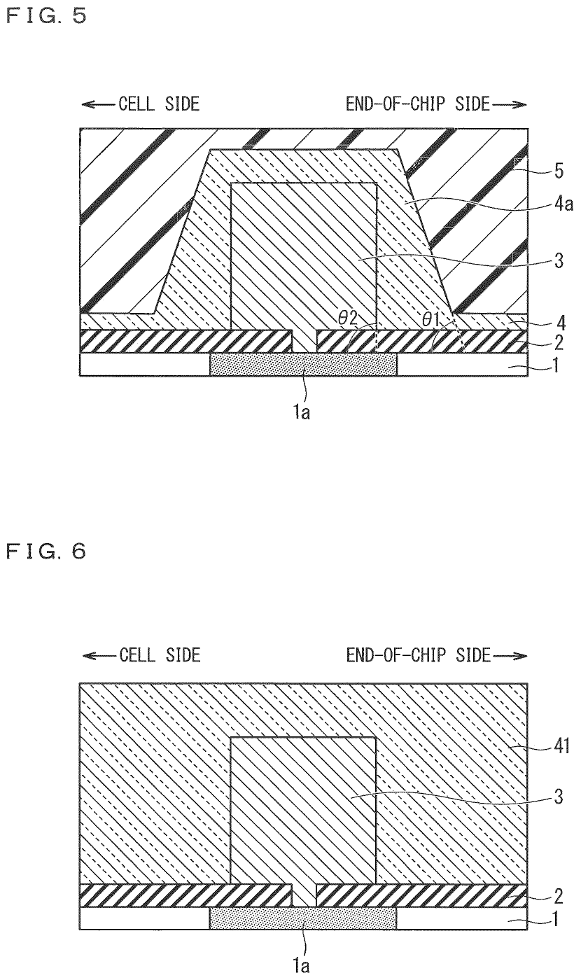

FIG. 5 is a cross-sectional view illustrating a structure of the termination region 83 of FIG. 1 in a semiconductor device according to Embodiment 2. The first surface electrode 3 is made of, for example, AlSi. Although the first surface electrode 3 in FIG. 5 substantially corresponds to only the first metal portion 3a described in Embodiment 1, the first surface electrode 3 according to Embodiment 2 may include the second metal portion 3b described in Embodiment 1.

In Embodiment 2, a first angle θ1 between the side surface of the cover portion 4a and the upper surface of the semiconductor substrate 1 on the cover portion 4a side is smaller in a cross-sectional view than a second angle θ2 between the side surface of the first surface electrode 3 and the upper surface of the semiconductor substrate 1 on the first surface electrode 3 side. With a second structure in which the first angle θ1 is smaller than the second angle θ2, the cover portion 4a of the glass coat 4 which covers the first surface electrode 3 has a tapered shape such that the cover portion 4a becomes wider as the cover portion 4a is closer to the semiconductor substrate 1 in a cross-sectional view.

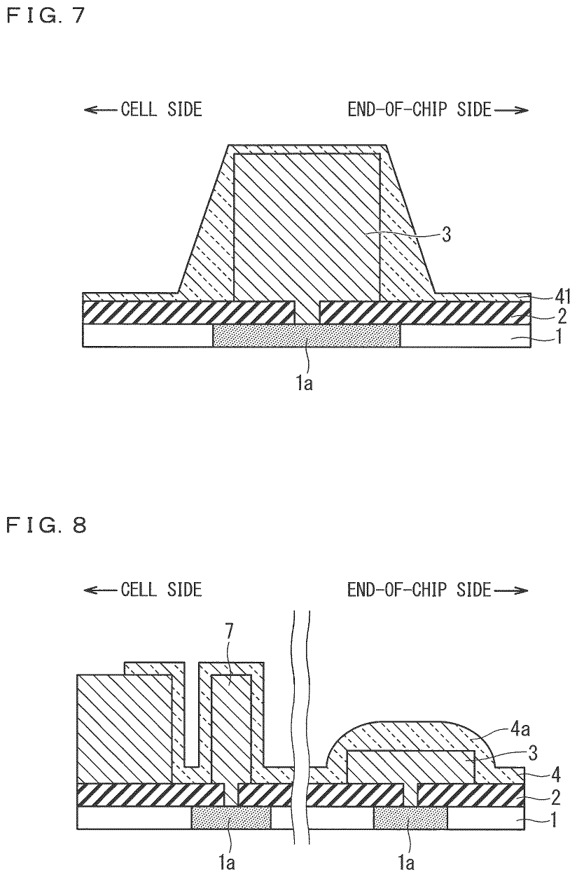

FIGS. 6 and 7 are cross-sectional views illustrating processes of manufacturing the semiconductor device according to Embodiment 2. First, as illustrated in FIG. 6, the insulating film 2 having a contact hole is formed on the upper surface of the semiconductor substrate 1. Then, for example, the first surface electrode 3 made of, for example, AlSi is formed on the guard ring region 1a and the insulating film 2 through the film formation process and patterning. Next, a SInSiN film 41 continuously covering the insulating film 2 and the first surface electrode 3 is formed through the film formation process.

Then, as illustrated in FIG. 7, an anisotropic half etching process is performed on the SInSiN film 41 so that the SInSiN film 41 has a target thickness and a tapered shape. Then, a SiN film is formed on the SInSiN film 41 through the film formation process. This completes the glass coat 4 including the SInSiN film 41 and the SiN film. The glass coat 4 in FIG. 5 is thicker than the SInSiN film 41 in FIG. 7 by the thickness of the SiN film.

The cover portion 4a of the glass coat 4 has a tapered shape in a cross-sectional view, with the second structure in which the first angle θ1 is smaller than the second angle θ2. Then, forming the polyimide film 5 covering the glass coat 4 completes the semiconductor device in FIG. 5.

### Summary of Embodiment 2

In the semiconductor device according to Embodiment 2, the glass coat 4 includes the cover portion 4a covering the first surface electrode 3, the cover portion 4a having a tapered shape such that the cover portion 4a becomes wider as the cover portion 4a is closer to the semiconductor substrate 1 in a cross-sectional view. Since such a structure can prevent cracks similarly to Embodiment 1, the reliability of the semiconductor device can be enhanced.

### Embodiment 3

FIG. 8 is a cross-sectional view illustrating a structure of the termination region 83 of FIG. 1 in a semiconductor device according to Embodiment 3. The lower the first surface electrode 3 with respect to the upper surface of the insulating film 2 is, the more easily the tapered shape of the cover portion 4a described in Embodiments 1 and 2 can be formed. However, when a surface electrode such as the first surface electrode 3 is low, there is a probability that the surface electrode has cracks in wire bonding the surface electrode in a latter process.

Thus, the semiconductor substrate 1 in Embodiment 3 includes a plurality of ring-shaped guard ring regions 1a as illustrated in FIG. 8. Here, a surface electrode connected to the guard ring region 1a at the outermost circumference is lower than another surface electrode. The structure of the semiconductor device according to Embodiment 3 will be hereinafter described in detail.

The structure according to Embodiment 3 is identical to a structure obtained by adding a second surface electrode 7 to the structure of Embodiment 2. The second surface electrode 7 is farther from the end of the semiconductor substrate 1 than the first surface electrode 3. In other words, the second surface electrode 7 is closer to the cell region 81 than the first surface electrode 3.

The guard ring region 1a at the outermost circumference is electrically connected to the first surface electrode 3 through a contact hole in the insulating film 2, and the other guard ring region 1a is electrically connected to the second surface electrode 7 through respective contact hole in the insulating film 2. The first surface electrode 3 is lower than the second surface electrode 7 with respect to the upper surface of the insulating film 2. The glass coat 4 may cover the second surface electrode 7, or a cover portion of the glass coat 4 which covers the second surface electrode 7 may have a tapered shape such that the cover portion becomes wider as the cover portion is closer to the semiconductor substrate 1 in a cross-sectional view.

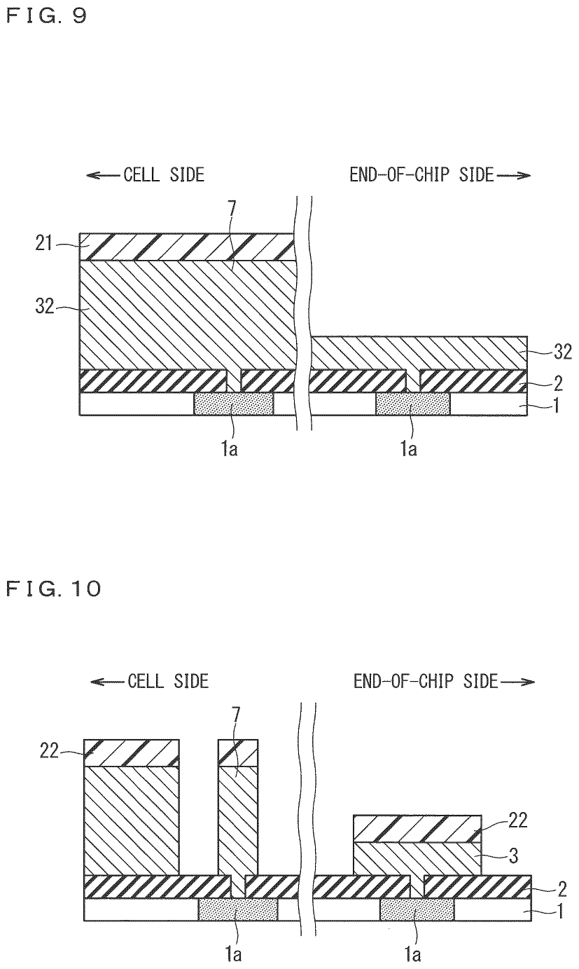

FIGS. 9 and 10 are cross-sectional views illustrating processes of manufacturing the semiconductor device according to Embodiment 3. First, as illustrated in FIG. 9, the insulating film 2 having contact holes is formed on the upper surface of the semiconductor substrate 1. Then, for example, a conductive component 32 made of, for example, AlSi is formed on the guard ring regions 1a and the insulating film 2 through the film formation process. Next, a resist 21 is formed, a half etching process is performed on the conductive component 32, and the resist 21 is removed so that an upper portion of the conductive component 32 which corresponds to the first surface electrode 3 is removed.

Then, a resist 22 is formed, an etching process is performed on the conductive component 32, and the resist 22 is removed so that the first surface electrode 3 is formed on the guard ring region 1a at the outermost circumference and the second surface electrode 7 is formed on the other guard ring region 1a as illustrated in FIG. 10. Since the upper portion of the conductive component 32 which corresponds to the first surface electrode 3 has already been removed, the first surface electrode 3 is lower than the second surface electrode 7 with respect to the upper surface of the insulating film 2.

Then, forming the glass coat 4 similarly to Embodiment 2 allows the cover portion 4a of the glass coat 4 which covers the first surface electrode 3 to have a tapered shape in a cross-sectional view. Then, forming the polyimide film 5 covering the glass coat 4 completes the semiconductor device in FIG. 8.

### Summary of Embodiment 3

In the semiconductor device according to Embodiment 3, the first surface electrode 3 is lower than the second surface electrode 7 with respect to the upper surface of the insulating film 2, the second surface electrode 7 being farther from the end of the semiconductor substrate 1 than the first surface electrode 3. Such a structure can easily form a tapered shape of the cover portion 4a covering the first surface electrode 3, and can reduce cracks in the second surface electrode 7 which is caused by, for example, wire bonding.

Although the number of the first surface electrodes 3 is one in the aforementioned description, the number may be multiple when the semiconductor device includes the second surface electrode 7. Although the use of Embodiment 3 in Embodiment 2 is described above, Embodiment 3 may be used in Embodiment 1. These are the same with Embodiment 4 and subsequent Embodiments.

### Embodiment 4

The structure of the termination region 83 in a semiconductor device according to Embodiment 4 is identical to that in the semiconductor device according to Embodiment 3 which is illustrated in FIG. 8. In Embodiment 3, performing the etching process on the conductive component 32 twice (the etching process and the half etching process) forms the first surface electrode 3 and the second surface electrode 7. In contrast, performing the etching process on the conductive component 32 once can form the first surface electrode 3 and the second surface electrode 7 in Embodiment 4.

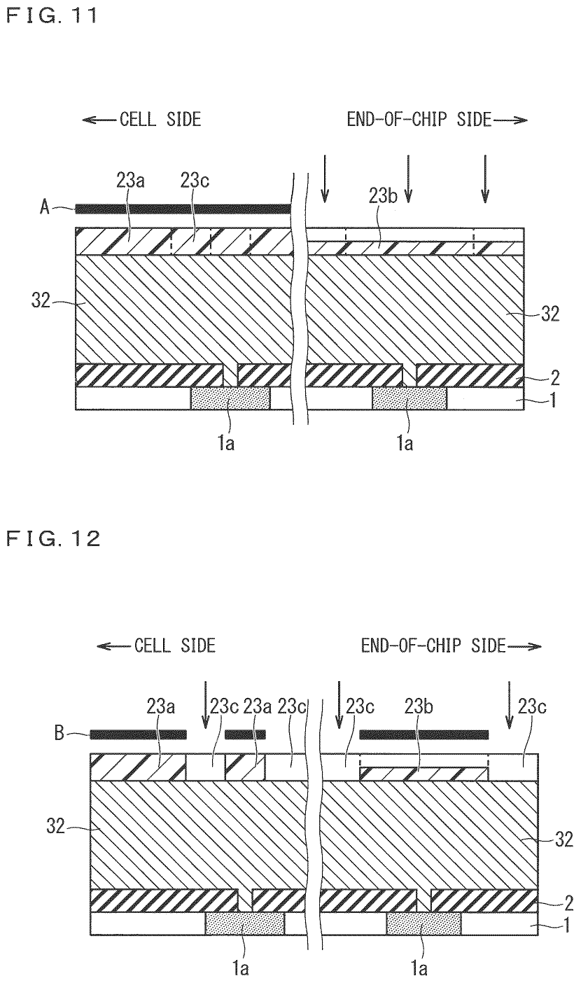

FIGS. 11 and 14 are cross-sectional views illustrating processes of manufacturing the semiconductor device according to Embodiment 4. First, a preparing process is performed which prepares the semiconductor substrate 1 having an upper surface on which the conductive component 32 made of AlSi is formed through the insulating film 2.

Next, a resist is applied to the conductive component 32, and an exposure process is performed. The exposure process according to Embodiment 4 includes a first exposure process and a second exposure process to be performed separately.

In the first exposure process, an upper portion of a resist 23b in a second region which corresponds to the first surface electrode 3 except a lower portion of the resist 23b is exposed to light using a mask A as illustrated in FIG. 11. In the first exposure process, an upper portion of a resist 23c in a third region may be exposed to light together with the upper portion of the resist 23b in the second region.

In the second exposure process, a resist 23c in a third region except a resist 23a in a first region which corresponds to the second surface electrode 7, and the resist 23b in the second region is exposed to light using a mask B as illustrated in FIG. 12. Although the second exposure process is performed after the first exposure process in this description, the first exposure process may be performed after the second exposure process.

As described above, an exposure process of exposing, to light, the upper portion of the resist 23b in the second region and the resist 23c in the third region except the resist 23a in the first region is performed as illustrated in FIG. 12.

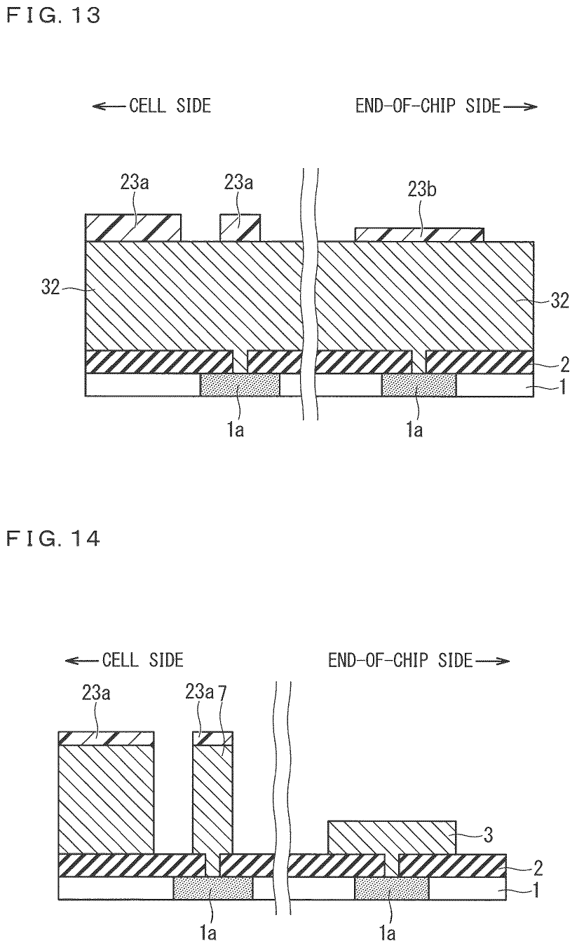

Then, a development process is performed which removes the upper portion of the resist 23b in the second region and the resist 23c in the third region which have been exposed to light as illustrated in FIG. 13. This allows the lower portion of the resist 23b in the second region and the resist 23a in the first region to remain.

Then, the etching process is performed which selectively etches the conductive component 32 using the lower portion of the resist 23b in the second region and the resist 23a in the first region. Consequently, not the conductive component 32 with the resist 23a in the first region, but the conductive component 32 without the resists 23a and 23b in the third region is etched. Furthermore, the thin resist 23b in the second region is removed during the etching process, and the conductive component 32 in the second region is half etched. Consequently, the first surface electrode 3 lower than the second surface electrode 7 is formed in the second region, and the second surface electrode 7 is formed in the first region that is farther from the end of the semiconductor substrate 1 than the second region as illustrated in FIG. 14.

Next, the resists 23a is removed. Then, forming the glass coat 4 continuously covering the insulating film 2 and the first surface electrode 3, and forming the polyimide film 5 covering the glass coat 4 similarly to Embodiment 3 completes the semiconductor device in FIG. 8.

### Summary of Embodiment 4

The method of manufacturing the semiconductor device according to Embodiment 4 can reduce the number of etching processes on the conductive component 32 more than that according to Embodiment 3.

### Embodiment 5

The structure of the termination region 83 in a semiconductor device according to Embodiment 5 is identical to that in the semiconductor device according to Embodiment 3 which is illustrated in FIG. 8. In Embodiment 4, the exposure process is performed twice (the first exposure process and the second exposure process to be performed separately). In contrast, the exposure process is performed once in Embodiment 5. The method of manufacturing the semiconductor device according to Embodiment 5 is identical to that according to Embodiment 4 except the exposure process. Thus, the exposure process will be hereinafter mainly described.

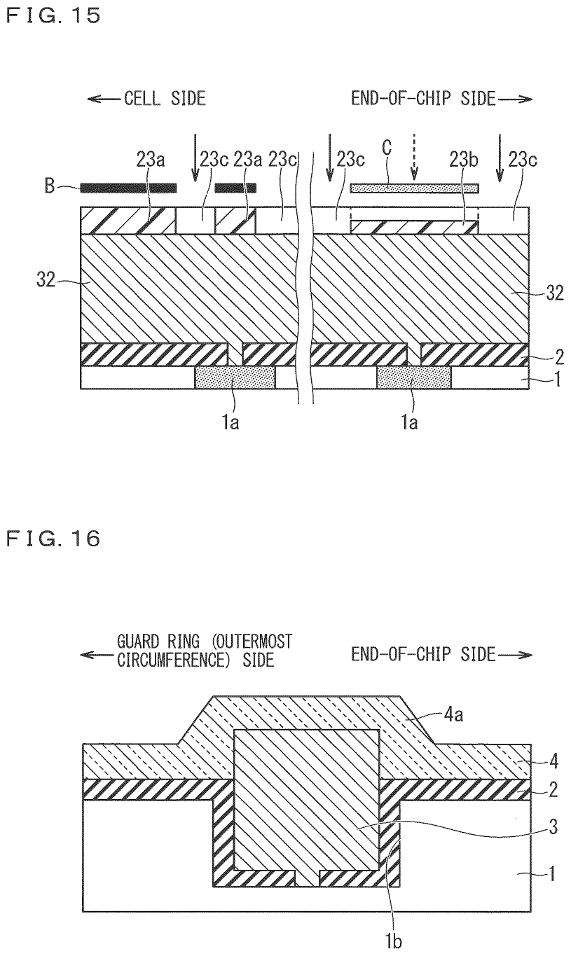

FIG. 15 is a cross-sectional view illustrating the exposure process in the processes of manufacturing the semiconductor device according to Embodiment 5. In Embodiment 5, the exposure process includes exposing, to light, the upper portion of the resist 23b in the second region using a semitransparent mask C simultaneously with the resist 23c in the third region using a transparent mask D except the resist 23a in the first region. The semitransparent mask C is made of, for example, a non-transparent material, a transparent material, and a semitransparent material. The transparent mask D is made of, for example, a non-transparent material and a transparent material.

### Summary of Embodiment 5

The method of manufacturing the semiconductor device according to Embodiment 5 can reduce the number of exposure processes more than that according to Embodiment 4.

### Embodiment 6

FIG. 16 is a cross-sectional view illustrating a structure of the termination region 83 of FIG. 1 in a semiconductor device according to Embodiment 6. In Embodiment 6, a trench 1b is formed in a non-implantation region between the guard ring region 1a at the outermost circumference of the semiconductor substrate 1 and the end of the semiconductor substrate 1. When the semiconductor elements of the cell region 81 include electrodes such as the gate electrodes formed in trenches, the trench 1b may be formed together with the trenches of the semiconductor elements.

As illustrated in FIG. 16, at least the lower portion of the first surface electrode 3 is accommodated in the trench 1b provided on the semiconductor substrate 1. The height of the first surface electrode 3 with respect to the upper surface of the insulating film 2 is, for example, approximately 1 μm, and may be identical to the thickness of the glass coat 4.

### Summary of Embodiment 6

Since the first surface electrode 3 can be lowered with respect to the upper surface of the insulating film 2 in the semiconductor device according to Embodiment 6, the tapered shape of the cover portion 4a covering the first surface electrode 3 can be easily formed. The semiconductor device may additionally include the second surface electrode 7 described in, for example, Embodiment 3, although Embodiment 6 does not describe such a structure. This is the same with next Embodiment 7.

### Embodiment 7

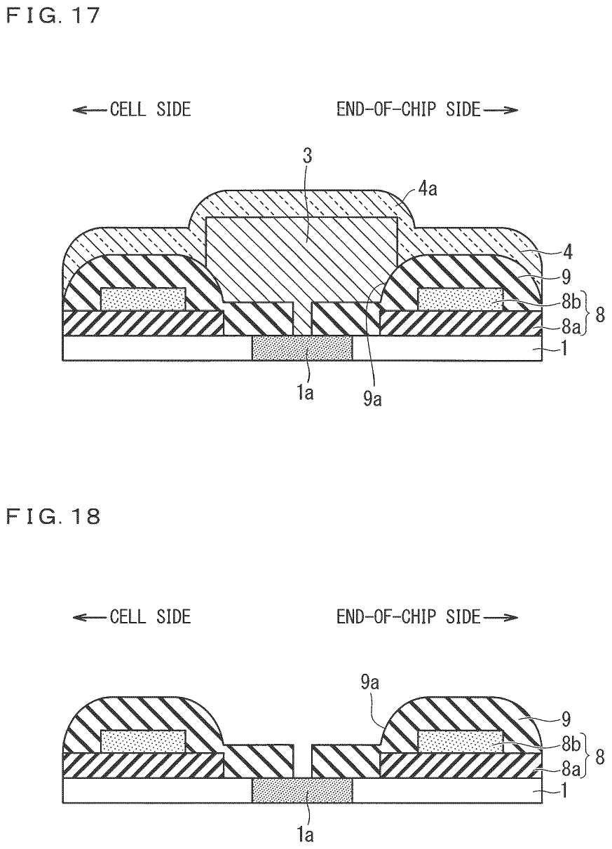

FIG. 17 is a cross-sectional view illustrating a structure of the termination region 83 of FIG. 1 in a semiconductor device according to Embodiment 7. The semiconductor device additionally includes pattern portions 8. The pattern portions 8 are formed between the semiconductor substrate 1 and an insulating film 9 that is an interlayer film in a cross-sectional view. Furthermore, the pattern portions 8 are formed, for example, on both sides of the first surface electrode 3 connected to the guard ring region 1a at the outermost circumference through a contact hole of the insulating film 9.

Each of the pattern portions 8 includes an oxide film 8a and a polyimide layer 8b. The oxide film 8a is formed on the semiconductor substrate 1, similarly to the insulating film 2 described in Embodiment 1. The polyimide layer 8b is formed on the oxide film 8a, and is formed inside an outline of the oxide film 8a in a plan view.

Reflecting the shape of the pattern portions 8 on the shape of the insulating film 9 in a cross-sectional view allows providing a recess 9a on the insulating film 9. Furthermore, the recess 9a on the insulating film 9 accommodates at least the lower portion of the first surface electrode 3. The height of the first surface electrode 3 with respect to the upper surface of the insulating film 9 is, for example, approximately 1 μm, and may be identical to the thickness of the glass coat 4.

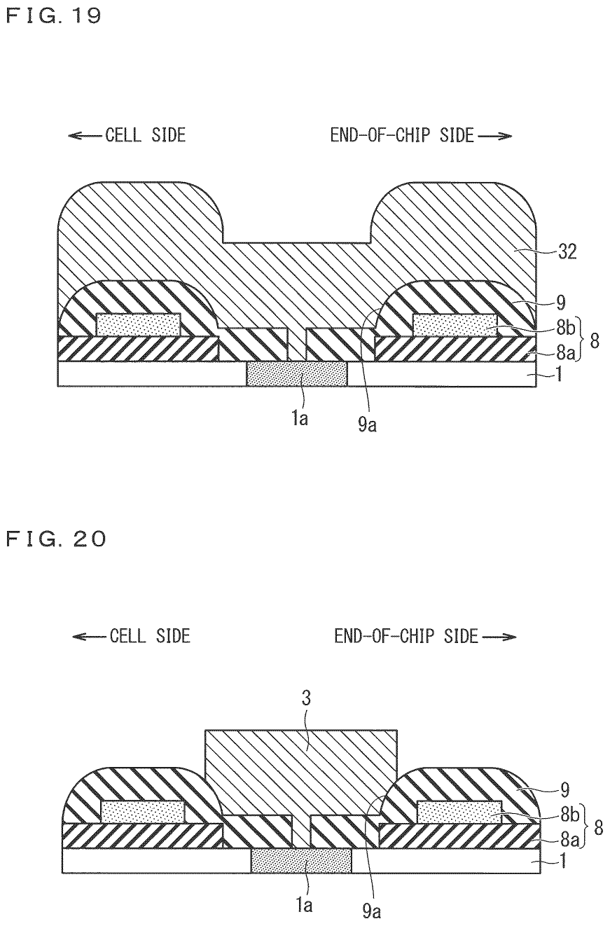

FIGS. 18 and 20 are cross-sectional views illustrating processes of manufacturing the semiconductor device according to Embodiment 7. First, the oxide films 8a, the polyimide layers 8b, and the insulating film 9 are formed in this order on the semiconductor substrate 1 through the film formation process and patterning as illustrated in FIG. 18. Reflecting the shape of the pattern portions 8 on the shape of the insulating film 9 in a cross-sectional view allows providing the recess 9a on the insulating film 9.

Then, for example, the conductive component 32 made of, for example, AlSi is formed on the guard ring region 1a and the insulating film 9 through the film formation process as illustrated in FIG. 19. Next, patterning the conductive component 32 forms the first surface electrode 3 at least the lower portion of which is accommodated in the recess 9a as illustrated in FIG. 20. Then, forming the glass coat 4 continuously covering the insulating film 9 and the first surface electrode 3, and forming the polyimide film 5 covering the glass coat 4 similarly to Embodiment 1 completes the semiconductor device in FIG. 17.

### Summary of Embodiment 7

Since the first surface electrode 3 can be lowered with respect to the upper surface of the insulating film 9 in the semiconductor device according to Embodiment 7, the tapered shape of the cover portion 4a covering the first surface electrode 3 can be easily formed. Furthermore, the first surface electrode 3 can be lowered even in a region of the semiconductor substrate 1 where the trench 1b described in Embodiment 6 cannot be formed due to, for example, design constraints.

Embodiments and modifications can be combined without restraint, and appropriately modified or omitted.

A summary of various aspects of the present disclosure will be hereinafter described as Appendixes.

### APPENDIX 1

A semiconductor device, comprising:
a semiconductor substrate having an end;
an insulating film along an upper surface of the semiconductor substrate;
a first surface electrode selectively provided on the insulating film; and
a passivation film covering the insulating film and the first surface electrode, wherein the passivation film includes a cover portion covering the first surface electrode, the cover portion having a tapered shape with at least one of a first structure or a second structure such that the cover portion becomes wider as the cover portion is closer to the semiconductor substrate in a cross-sectional view,
in the first structure, the first surface electrode includes a first metal portion, and a second metal portion made of a metal with corrosion resistance higher than corrosion resistance of the first metal portion, the second metal portion being in contact with a side surface of the first metal portion on a same side as the end of the semiconductor substrate in a plan view, and having a tapered shape such that the second metal portion becomes wider as the second metal portion is closer to the semiconductor substrate in the cross-sectional view, and
in the second structure, a first angle between a side surface of the cover portion and the upper surface of the semiconductor substrate on the cover portion side is smaller in the cross-sectional view than a second angle between a side surface of the first surface electrode and the upper surface of the semiconductor substrate on the first surface electrode side.

### APPENDIX 2

The semiconductor device according to appendix 1, further comprising
a second surface electrode on the insulating film, the second surface electrode being farther from the end of the semiconductor substrate than the first surface electrode,
wherein the semiconductor substrate includes a plurality of ring-shaped guard ring regions each electrically connected to one of the first surface electrode and the second surface electrode through a contact hole of the insulating film, and
the first surface electrode is lower than the second surface electrode with respect to the upper surface of the insulating film.

### APPENDIX 3

The semiconductor device according to appendix 1 or 2,
wherein at least a lower portion of the first surface electrode is accommodated in a trench provided on the semiconductor substrate.

### APPENDIX 4

The semiconductor device according to appendix 1 or 2, further comprising
pattern portions between the semiconductor substrate and the insulating film and on both sides of the first surface electrode in the cross-sectional view,
wherein reflecting a shape of the pattern portions on a shape of the insulating film in the cross-sectional view allows providing a recess on the insulating film, the recess accommodating at least a lower portion of the first surface electrode.

### APPENDIX 5

A method of manufacturing a semiconductor device, the method comprising:
a preparing process of preparing a semiconductor substrate having an upper surface on which a conductive component is formed through an insulating film;
an exposure process of applying a resist to the conductive component, and exposing, to light, an upper portion of the resist in a second region and the resist in a third region except the resist in a first region; and
a development process of removing the upper portion of the resist in the second region and the resist in the third region which have been exposed to light;
an etching process of selectively etching the conductive component using a lower portion of the resist in the second region and the resist in the first region to form a first surface electrode, and a second surface electrode farther from an end of the semiconductor substrate than the first surface electrode, the first surface electrode being lower than the second surface electrode with respect to an upper surface of the insulating film; and
a film formation process of forming a passivation film covering the insulating film and the first surface electrode, the passivation film including a cover portion covering the first surface electrode, the cover portion having a tapered shape such that the cover portion becomes wider as the cover portion is closer to the semiconductor substrate in a cross-sectional view.

### APPENDIX 6

The method according to appendix 5,
wherein the exposure process includes exposing, to light, the upper portion of the resist in the second region and the resist in the third region separately.

### APPENDIX 7

The method according to appendix 5,
wherein the exposure process includes exposing, to light, the upper portion of the resist in the second region using a semitransparent mask simultaneously with the resist in the third region using a transparent mask.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor substrate having an end;
an insulating film along an upper surface of the semiconductor substrate;
a first surface electrode selectively provided on the insulating film; and
a passivation film covering the insulating film and the first surface electrode,
wherein the passivation film includes a cover portion covering the first surface electrode, the cover portion having a tapered shape with at least one of a first structure or a second structure such that the cover portion becomes wider as the cover portion is closer to the semiconductor substrate in a cross-sectional view,
in the first structure, the first surface electrode includes a first metal portion, and a second metal portion made of a metal with corrosion resistance higher than corrosion resistance of the first metal portion, the second metal portion being in contact with a side surface of the first metal portion on a same side as the end of the semiconductor substrate in a plan view, and having a tapered shape such that the second metal portion becomes wider as the second metal portion is closer to the semiconductor substrate in the cross-sectional view, and
in the second structure, a first angle between a side surface of the cover portion and the upper surface of the semiconductor substrate on the cover portion side is smaller in the cross-sectional view than a second angle between a side surface of the first surface electrode and the upper surface of the semiconductor substrate on the first surface electrode side.

2. The semiconductor device according to claim 1, further comprising
a second surface electrode on the insulating film, the second surface electrode being farther from the end of the semiconductor substrate than the first surface electrode,
wherein the semiconductor substrate includes a plurality of ring-shaped guard ring regions each electrically connected to one of the first surface electrode and the second surface electrode through a contact hole of the insulating film, and
the first surface electrode is lower than the second surface electrode with respect to the upper surface of the insulating film.

3. The semiconductor device according to claim 1,
wherein at least a lower portion of the first surface electrode is accommodated in a trench provided on the semiconductor substrate.

4. The semiconductor device according to claim 1, further comprising
pattern portions between the semiconductor substrate and the insulating film and on both sides of the first surface electrode in the cross-sectional view,
wherein reflecting a shape of the pattern portions on a shape of the insulating film in the cross-sectional view allows providing a recess on the insulating film, the recess accommodating at least a lower portion of the first surface electrode.

5. A method of manufacturing a semiconductor device, the method comprising:
a preparing process of preparing a semiconductor substrate having an upper surface on which a conductive component is formed through an insulating film;
an exposure process of applying a resist to the conductive component, and exposing, to light, an upper portion of the resist in a second region and the resist in a third region except the resist in a first region;
a development process of removing the upper portion of the resist in the second region and the resist in the third region which have been exposed to light;
an etching process of selectively etching the conductive component using a lower portion of the resist in the second region and the resist in the first region to form a first surface electrode, and a second surface electrode farther from an end of the semiconductor substrate than the first surface electrode, the first surface electrode being lower than the second surface electrode with respect to an upper surface of the insulating film; and
a film formation process of forming a passivation film covering the insulating film and the first surface electrode, the passivation film including a cover portion covering the first surface electrode, the cover portion having a tapered shape such that the cover portion becomes wider as the cover portion is closer to the semiconductor substrate in a cross-sectional view.

6. The method according to claim 5,
wherein the exposure process includes exposing, to light, the upper portion of the resist in the second region and the resist in the third region separately.

7. The method according to claim 5,
wherein the exposure process includes exposing, to light, the upper portion of the resist in the second region using a semitransparent mask simultaneously with the resist in the third region using a transparent mask.

8. The semiconductor device according to claim 2,
wherein at least a lower portion of the first surface electrode is accommodated in a trench provided on the semiconductor substrate.

9. The semiconductor device according to claim 2, further comprising
pattern portions between the semiconductor substrate and the insulating film and on both sides of the first surface electrode in the cross-sectional view,
wherein reflecting a shape of the pattern portions on a shape of the insulating film in the cross-sectional view allows providing a recess on the insulating film, the recess accommodating at least a lower portion of the first surface electrode.
